(19) United States
(12) Patent Application Publication
(10) Pub. No.: US 2023/0332290 A1
(43) Pub. Date: Oct. 19, 2023

(54) SUBSTRATE PROCESSING APPARATUS, NOZZLE ASSEMBLY, SUBSTRATE PROCESSING METHOD, METHOD OF MANUFACTURING SEMICONDUCTOR DEVICE AND NON-TRANSITORY COMPUTER-READABLE RECORDING MEDIUM

(71) Applicant: Kokusai Electric Corporation, Tokyo (JP)

(72) Inventors: Hironori SHIMADA, Toyama-shi (JP); Mitsuro TANABE, Toyama-shi (JP); Toru KAGAYA, Toyama-shi (JP); Sadao HISAKADO, Toyama-shi (JP); Hidekazu KANASUGI, Toyama-shi (JP)

(73) Assignee: Kokusai Electric Corporation, Tokyo (JP)

(21) Appl. No.: 18/337,174

(22) Filed: Jun. 19, 2023

Related U.S. Application Data
(63) Continuation of application No. PCT/JP2021/041846, filed on Nov. 15, 2021.

(30) Foreign Application Priority Data
Dec. 20, 2020 (JP) 2020-210899

(51) Int. Cl. C23C 16/455; C23C 16/52; C23C 16/46

(52) U.S. Cl. CPC C23C 16/45563; C23C 16/52; C23C 16/46

(57) ABSTRACT

According to one aspect of the technique of the present disclosure, there is provided a substrate processing apparatus including a nozzle arranged along an inner wall surface of a process vessel and provided at least in a lower portion of the process vessel with a gap between the nozzle and the inner wall surface of the process vessel; a nozzle base supporting the nozzle and accommodating therein a flow path communicating with the nozzle; a support structure provided along the inner wall surface and joined to a first joint surface of the nozzle base that does not face the inner wall surface; and a tilt-adjusting structure for adjusting a tilt of the nozzle base at a position shifted toward a center of the process vessel and away from a center of gravity of a nozzle assembly comprising the nozzle and the nozzle base.

### CROSS-REFERENCE TO RELATED PATENT APPLICATION

This application is a bypass continuation application of PCT International Application No PCT/JP2021/041846, filed on Nov. 15, 2021, in the WIPO, the international application being based upon and claiming the benefit of priority from Japanese Patent Application No. 2020-210899, filed on Dec. 20, 2020, in the Japanese Patent Office, the entire contents of which are hereby incorporated by reference.

### BACKGROUND

### 1. Field

The present disclosure relates to a substrate processing apparatus, a nozzle assembly, a substrate processing method, a method of manufacturing semiconductor device and a non-transitory computer-readable recording medium.

### 2. Related Art

In a manufacturing process of a semiconductor device, for example, a vertical type substrate processing apparatus capable of collectively processing (that is, batch-processing) a plurality of substrates may be used. In the vertical substrate processing apparatus, a nozzle through which a process gas is supplied is connected and fixed to a gas introduction port provided in a manifold. Thereby, the nozzle is provided in a reaction tube of the vertical substrate processing apparatus in an up-down direction (vertical direction). When the nozzle is installed to be tilted in a front-rear direction, a tilt of the nozzle is adjusted by pushing up a mounting structure (which is a nozzle base) of the nozzle by an adjusting structure such that the nozzle is installed vertically.

### SUMMARY

According to the present disclosure, there is provided a technique capable of adjusting a tilt of a nozzle when a nozzle base is fixed on a surface that does not face an inner wall surface of a manifold.

According to one aspect of the technique of the present disclosure, there is provided a substrate processing apparatus including: a nozzle arranged along an inner wall surface of a process vessel and provided at least in a lower portion of the process vessel with a gap between the nozzle and the inner wall surface of the process vessel; a nozzle base configured to support the nozzle, wherein a flow path communicating with the nozzle is provided in the nozzle base; a support structure provided along the inner wall surface and joined to a first joint surface of the nozzle base, wherein the first joint surface of the nozzle base does not face the inner wall surface; and a tilt-adjusting structure configured to be capable of adjusting a tilt of the nozzle base at a position shifted toward a center of the process vessel and away from a center of gravity of a nozzle assembly comprising the nozzle and the nozzle base.

### BRIEF DESCRIPTION OF THE DRAWINGS

FIG. 1 is a diagram schematically illustrating a substrate processing apparatus according to one or more embodiments of the present disclosure.

FIG. 2 is a diagram schematically illustrating a cross-section of a process furnace of the substrate processing apparatus shown in FIG. 1.

FIG. 3 is a perspective view schematically illustrating an offset arrangement of a nozzle and a gas introduction port in the substrate processing apparatus according to the embodiments of the present disclosure.

FIG. 4 is a front view schematically illustrating configurations around the nozzle base shown in FIG. 3.

FIG. 5 is a diagram schematically illustrating a cross-section taken along a line D-D shown in FIG. 4.

FIG. 6 is a diagram schematically illustrating a cross-section taken along a line E-E shown in FIG. 4.

FIG. 7 is a bottom view schematically illustrating the configurations around the nozzle base shown in FIG. 4.

FIG. 8 is a diagram schematically illustrating a center of gravity and a fulcrum.

FIG. 9 is a flow chart of a method of manufacturing a semiconductor device apparatus according to the embodiments of the present disclosure.

FIG. 10 is a bottom view schematically illustrating a cross-section of configurations around the nozzle base according to a modified example.

### DETAILED DESCRIPTION

### Embodiments of Present Disclosure

Hereinafter, one or more embodiments (also simply referred to as “embodiments”) according to the technique of the present disclosure will be described with reference to the drawings. The same or corresponding reference numerals represent the same or corresponding components in the drawings, and redundant descriptions related thereto will be omitted. When describing a nozzle, a direction toward a center of a process vessel may also be referred to as a “front direction”, and a direction outward from the center of the process vessel may also be referred to as a “rear direction”. Further, a direction toward an upper portion of the process vessel may also be referred to as an “upper direction”, and a direction toward a lower portion of the process vessel may also be referred to as a “lower direction”. In the present specification, the drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

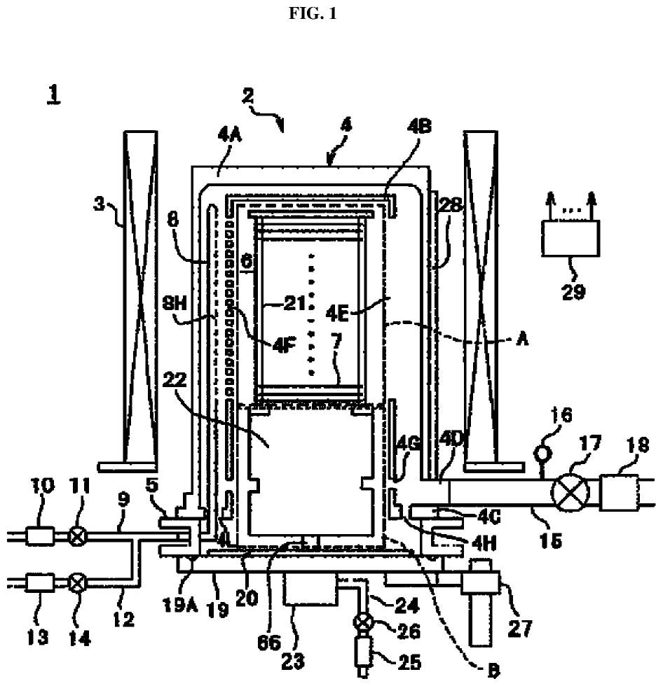

As shown in FIG. 1, a substrate processing apparatus 1 according to the present embodiments is configured as a vertical type heat treatment apparatus capable of performing a heat treatment process in a manufacturing process of a semiconductor integrated circuit, and includes a process furnace 2. The process furnace 2 includes a heater 3 in order to uniformly heat the process furnace 2. The heater 3 is constituted by a plurality of heating structures. The heater 3 is of a cylindrical shape, and is installed perpendicular to an installation floor of the substrate processing apparatus 1 while being supported by a heater base (not shown) serving as a support plate. The heater 3 also functions as an activator (also referred to as is an “exciter”) capable of activating (or exciting) a gas such as a source gas and a reactive gas by heat as described later.

A reaction tube 4 constituting a reaction vessel is provided in an inner side of the heater 3. For example, the reaction tube 4 is made of a heat resistant material such as quartz (SiO₂) and silicon carbide (SiC), and is of a cylindrical shape. The reaction tube 4 is embodied by a double tube structure including an outer tube 4A and an inner tube 4B that are coupled to each other at a flange 4C provided at a lower portion of the reaction tube 4. Upper ends of the outer tube 4A and the inner tube 4B are closed by ceilings, respectively, and a lower end of the inner tube 4B is open. An outer diameter of the flange 4C is greater than an outer diameter of the outer tube 4A. The flange 4C protrudes outward from an outer periphery of the outer tube 4A. An exhaust outlet 4D serving as an exhaust port and communicating with an inside of the outer tube 4A is provided in the vicinity of a lower end of the reaction tube 4. An exhaust space S is provided between the outer tube 4A and the inner tube 4B. The reaction tube 4 including the above-described components such as the outer tube 4A and the inner tube 4B is formed as a single body of a single material. The outer tube 4A is thicker than the inner tube 4B so as to withstand a pressure difference when the inside thereof is exhausted to vacuum.

A manifold 5 is a flange tube of a cylindrical shape or of a truncated cone shape made of a material such as a metal or quartz, and is provided to support the lower end of the reaction tube 4. An inner diameter of the manifold 5 is greater than an inner diameter of the reaction tube 4 (and an inner diameter of the flange 4C). As a result, an annular space is defined between the lower end of the reaction tube 4 (that is, the flange 4C) and a seal cap 19 described later. The annular space and configurations around the annular space may be collectively or individually referred to as a “furnace opening”. The process vessel is constituted by the reaction tube 4 and the manifold 5, and a process chamber 6 in which a wafer 7 serving as a substrate is processed is provided inside the process vessel.

The inner tube 4B is provided with a main exhaust port 4E and a plurality of supply slits 4F. The main exhaust port 4E is provided at the inner tube 4B and above the exhaust outlet 4D of the reaction tube 4. The main exhaust port 4E is configured to communicate with an inside and an outside of the inner tube 4B on a side thereof. The supply slits 4F are provided (bored) at the inner tube 4B at positions opposite to the main exhaust port 4E. The main exhaust port 4E is a single vertically elongated opening that opens to a region where a plurality of wafers including a wafer 7 are disposed. Hereinafter, the plurality of wafers including the wafer 7 may also be simply referred to as “wafers 7”. Each of the supply slits 4F is a slit extending in a circumferential direction of the inner tube 4B. The supply slits 4F are arranged in a vertical direction so as to face the wafers 7, respectively.

The inner tube 4B is also provided with an intermediate exhaust port 4G. The intermediate exhaust port 4G is provided at the inner tube 4B closer to a center of the reaction tube 4 than the exhaust outlet 4D and closer to a lower end opening of the reaction tube 4 than the main exhaust port 4E. The intermediate exhaust port 4G is configured such that the process chamber 6 and the exhaust space S (which is an exhaust chamber) communicate with each other through the intermediate exhaust port 4G. The intermediate exhaust port 4G is provided in the same direction as the exhaust outlet 4D, and is arranged at a height such that at least a part of an opening thereof overlaps with a pipe of the exhaust outlet 4D. The flange 4C is also provided with one or more bottom exhaust ports 4H. The one or more bottom exhaust ports 4H are configured such that the process chamber 6 and a lower end of the exhaust space S communicate with each other through the one or more bottom exhaust ports 4H. In other words, the lower end of the exhaust space S is closed by the flange 4C except where the one or more bottom exhaust ports 4H and a nozzle insertion hole 4L described later are provided. The intermediate exhaust port 4G and the one or more bottom exhaust ports 4H are configured such that a shaft purge gas described later is mainly exhausted therethrough.

Between the outer tube 4A and the inner tube 4B, one or more nozzles 8 through which a process gas such as the source gas is supplied are provided corresponding to the positions of the supply slits 4F. One or more gas supply pipes 9 through which the process gas such as the source gas is supplied are connected to the one or more nozzles 8 through the manifold 5, respectively.

A mass flow controller (MFC) 10 serving as a flow rate controller and a valve 11 serving as an opening/closing valve are sequentially installed in this order on flow paths of the one or more gas supply pipes 9 from upstream sides to downstream sides thereof. One or more gas supply pipes 12 through which an inert gas is supplied are connected to the one or more gas supply pipes 9, respectively, at a downstream side of the valve 11. An MFC 13 and a valve 14 are sequentially installed in this order at the one or more gas supply pipes 12 from upstream sides to downstream sides thereof. Hereinafter, the one or more nozzles 8 may also be collectively or individually referred to as a “nozzle 8”, the one or more gas supply pipes 9 may also be collectively or individually referred to as a “gas supply pipe 9”, and the one or more gas supply pipes 12 may also be collectively or individually referred to as a “gas supply pipe 12”. A process gas supplier serving as a process gas supply system or a process gas supply structure is constituted mainly by the gas supply pipe 9, the MFC 10 and the valve 11. A gas supplier serving as a gas supply system or a gas supply structure is constituted mainly by the process gas supplier, the MFC 13 and the valve 14.

The nozzle 8 serving as an injector is provided in a nozzle chamber 42 so as to extend straight from the lower portion of the reaction tube 4 toward an upper portion of the reaction tube 4. One or more nozzle holes 8H through which the gas such as the process gas is supplied may be provided on an upper end or a side surface of the nozzle 8. The nozzle holes 8H are open to face openings of the supply slits 4F, respectively. The nozzle holes 8H are open toward the center of the reaction tube 4. As a result, it is possible to inject the gas toward the wafer 7 through the inner tube 4B.

An exhaust pipe 15 through which an inner atmosphere of the process chamber 6 is exhausted is connected to the exhaust outlet 4D. A vacuum pump 18 serving as a vacuum exhaust apparatus is connected to the exhaust pipe 15 through a pressure sensor 16 and an APC (Automatic Pressure Controller) valve 17. The pressure sensor 16 serves as a pressure detector (also referred to as a “pressure meter”) to detect an inner pressure of the process chamber 6, and the APC valve 17 serves as a pressure regulator (also referred to as a “pressure adjusting structure”). With the vacuum pump 18 in operation, the APC valve 17 may be opened or closed to perform a vacuum exhaust of the inner atmosphere of the process chamber 6 or stop the vacuum exhaust. In addition, with the vacuum pump 18 in operation, an opening degree of the APC valve 17 may be adjusted based on pressure information detected by the pressure sensor 16, in order to control the inner pressure of the process chamber 6. An exhauster (which is an exhaust system or an exhaust structure) is constituted mainly by the exhaust pipe 15, the APC valve 17 and the pressure sensor 16. The exhauster may further include the vacuum pump 18.

The seal cap 19 serving as a furnace opening lid capable of airtightly sealing a lower end opening of the manifold 5 is provided under the manifold 5. The seal cap 19 is made of a metal such as SUS (stainless steel) and a nickel-based alloy, and is of a disk shape. An O-ring 19A serving as a seal is provided on an upper surface of the seal cap 19 so as to be in contact with a lower end of the manifold 5.

A cover plate 20 is also provided on the upper surface of the seal cap 19 so as to protect a portion of the seal cap 19 inner than an inner periphery of the lower end of the manifold 5. For example, the cover plate 20 is made of a heat and corrosion resistant material such as quartz, sapphire and SiC, and is of a disk shape.

A boat 21 serving as a substrate retainer is configured to align the wafers 7 (for example, 25 to 200 wafers) in the vertical direction so as to support the wafers 7 in a multistage manner while the wafers 7 are horizontally oriented with their centers aligned with one another. In such a state, the boat 21 supports the wafers 7 with a predetermined interval therebetween. For example, the boat 21 is made of a heat resistant material such as quartz and SiC. It may be preferable to minimize the inner diameter of the reaction tube 4 as long as the boat 21 can be safely transferred into and out of the reaction tube 4.

A heat insulating assembly 22 is disposed below the boat 21. The heat insulating assembly 22 is embodied by a structure in which conduction or transmission of the heat tends to reduce in the vertical direction. It is possible to purge an inside of the heat insulating assembly 22 with the shaft purge gas. The upper portion of the reaction tube 4 where the boat 21 is disposed may also be referred to as a “process region A”, and the lower portion of the reaction tube 4 where the heat insulating assembly 22 is disposed may be referred to as a “heat insulating region B”.

A rotator 23 configured to rotate the boat 21 is provided under the seal cap 19 opposite to the process chamber 6. A gas supply pipe 24 of the shaft purge gas is connected to the rotator 23. An MFC 25 and a valve 26 are sequentially installed in this order at the gas supply pipe 24 from an upstream side to a downstream side of the gas supply pipe 24. One purpose of the shaft purge gas is to protect an inside of the rotator 23 (for example, bearings) from a corrosive gas and the like used in the process chamber 6. The shaft purge gas flows along a shaft of the rotator 23 and is finally discharged into the process chamber 6.

A boat elevator 27 is provided outside the reaction tube 4 vertically below the reaction tube 4. The boat elevator 27 serves as an elevating structure (or a transfer structure) capable of elevating and lowering the seal cap 19. As a result, the boat 21 supported by the seal cap 19 and the wafers 7 accommodated in the boat 21 may be transferred into or out of the process chamber 6. For example, there may be provided a shutter (not shown) configured to, instead of the seal cap 19, close the lower end opening of the reaction tube 4 while the seal cap 19 is being lowered to a lowest position thereof.

A temperature sensor 28 is installed on an outer wall of the outer tube 4A. The temperature sensor 28 may be embodied by a plurality of thermocouples arranged in a vertical array. The state of electric conduction to the heater 3 may be adjusted based on temperature information detected by the temperature sensor 28 such that a desired temperature distribution of an inner temperature of the process chamber 6 can be obtained.

A controller 29 is constituted by a computer configured to control the substrate processing apparatus 1. The controller 29 is electrically connected to components of the substrate processing apparatus 1 such as the MFCs 10 and 13, the valves 11 and 14, the pressure sensor 16, the APC valve 17, the vacuum pump 18, the heater 3, the temperature sensor 28, the rotator 23 and the boat elevator 27, and is configured to receive signals from the components described above or to control the components described above.

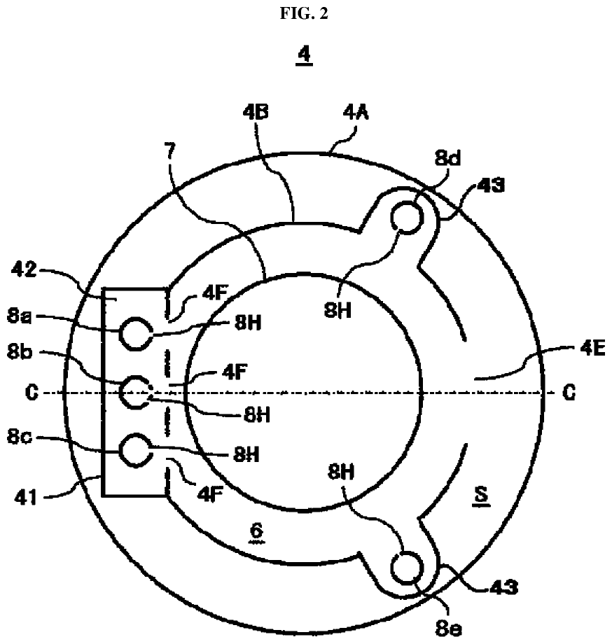

Subsequently, the reaction tube 4 will be described with reference to FIG. 2. The supply slits 4F through which the process gas is supplied into the process chamber 6 are provided in the inner tube 4B. The supply slits 4F are arranged in a lattice pattern. For example, the number of the supply slits 4F counted along the vertical direction (that is, the number of columns of the lattice pattern) is the same as the number of the wafers 7, and the number of the supply slits 4F counted along the horizontal direction (that is, the number of rows of the lattice pattern) is three. Alternatively, a supply slit 4F may be provided as a single opening commonly provided for the wafers 7 and nozzles 8a, 8b and 8c. A section separated from the exhaust space S by partition plates 41 may constitute the nozzle chamber 42 serving as a supply buffer. That is, the nozzle chamber 42 is formed by a part of a side portion of the inner tube 4B being projected outward. In the vicinity of the process region A, only the supply slits 4F directly communicate with the nozzle chamber 42 and the inside of the inner tube 4B.

The partition plates 41 according to the present embodiments are airtightly connected to the inner tube 4B, and the nozzle chamber 42 isolated from the exhaust space S is defined by an inner side of the partition plates 41. Further, the nozzle chamber 42 may not be completely isolated from the exhaust space S. The nozzle chamber 42 is not limited to an example in which the nozzle chamber 42 is constituted by a back plate of the partition plates 41 along an inner surface of the outer tube 4A. For example, an outer peripheral portion of the nozzle chamber 42 may be open and/or partitioned by the outer tube 4A. Alternatively, the partition plates 41 may be completely removed.

The inner tube 4B is provided with bulges 43 serving as a nozzle accommodating structure extending in the vertical direction and expanding outward. According to the present embodiments, for example, the bulges 43 are arranged one by one on both sides of the main exhaust port 4E at positions closer to the main exhaust port 4E than the nozzle chamber 42.

For example, the three nozzles 8a through 8c are installed in the nozzle chamber 42. The nozzle holes 8H, which are open toward the center of the reaction tube 4, are provided on side surfaces of the nozzles 8a through 8c, respectively. Although the gas ejected through the nozzle holes 8H is intended to flow from the supply slits 4F into the inner tube 4B, a part of the gas may not flow directly into the inner tube 4B.

Gas suppliers constituted by components such as the gas supply pipe 9, the valve 11, the MFC 10, the gas supply pipe 12, the valve 14 and the MFC 13 as shown in FIG. 1 are connected to the nozzles 8a through 8c, respectively. It is possible to supply different gases to the nozzles 8a through 8c using the gas suppliers. Each of the nozzles 8a through 8c is supported by the gas supply pipe 9 corresponding thereto or the manifold 5, and extends into the nozzle chamber 42 through the nozzle insertion hole 4L provided in the flange 4C. The process gas ejected through each of the nozzles 8a through 8c passes through the supply slits 4F, flows over the wafer 7, and is exhausted out of a furnace (that is, the process furnace 2) via the exhaust pipe 15 through the main exhaust port 4E facing the wafer 7. The gas remaining in the nozzle chamber 42 may also be discharged to the exhaust space S through the nozzle insertion hole 4L.

The two bulges 43 are provided with nozzles 8d and 8e, respectively. The nozzles 8d and 8e are arranged symmetrically with respect to a line C-C connecting a center of the nozzle chamber 42 and a center of the main exhaust port 4E. The nozzle holes 8H that open toward the wafers 7 are provided on side surfaces of the nozzles 8d and 8e, respectively. The nozzles 8d and 8e may be used for the purpose of suppressing or controlling a generation of a vortex in the process chamber 6 or locally diluting a film-forming gas such as the process gas so as to control a uniformity of a film (which is deposited on the wafer 7) on a surface of the wafer 7. Gas suppliers constituted by components such as the gas supply pipe 9, the valve 11, the MFC 10, the gas supply pipe 12, the valve 14 and the MFC 13 as shown in FIG. 1 are connected to the nozzles 8d and 8e, respectively. For example, nitrogen (N₂) gas serving as the inert gas is ejected from the nozzles 8d and 8e to collide with the process gas such that the film-forming gas stagnates on the wafers 7.

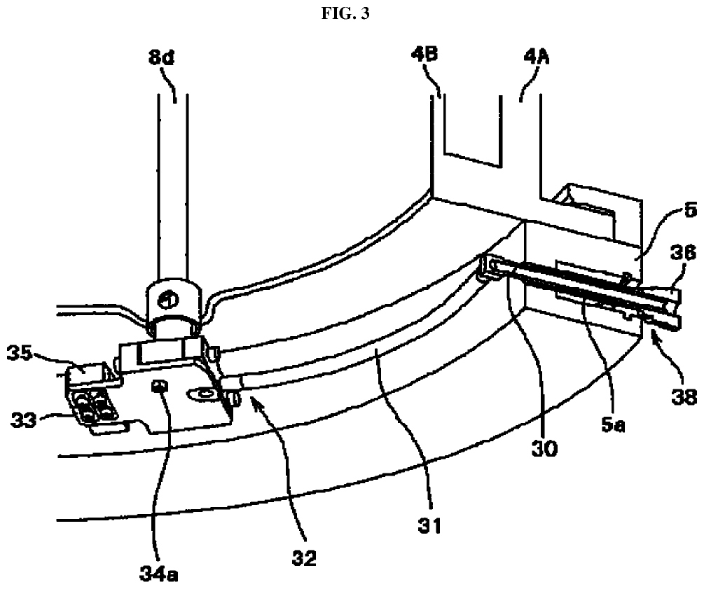

An installation operation of the nozzle 8d shown in FIG. 2 will be described with reference to FIG. 3. The manifold 5 is provided with a gas inlet port (gas introduction port) 38 extending outwardly through the side wall thereof. The gas inlet port 38 is provided with a connecting structure 36 connected to the gas supply pipe 9 at a front end (tip) thereof. A connecting pipe 30 of a cylindrical shape is inserted into the gas inlet port 38 from an inside of the manifold 5, and is airtightly sealed and fixed to the gas supply pipe 9 corresponding thereto at the connecting structure 36 by an O-ring (not shown) and the like. The N₂ gas is introduced to the nozzle 8d through the connecting pipe 30, passes through a gas supply pipe 31 of an arc shape provided along a circumferential direction of an inner wall surface 5b of the manifold 5, and is supplied to a nozzle base (elbow) 32 and the nozzle 8d. That is, the nozzle 8d and the gas inlet port 38 are distanced apart in the circumferential direction of the inner wall surface 5b of the manifold 5. For example, such a configuration is used when there is not enough space to install the gas inlet port 38 just outside the nozzle 8 and the like. For example, when a periphery of the manifold 5 is covered with a casing (scavenger) of a rectangular box shape, an empty space may vary depending on a position in the circumferential direction.

A support structure 33 fixed to the manifold 5 via a bracket 35 is provided with a bolt 34a serving as a tilt-adjusting structure, and the nozzle base 32 is supported by the bolt 34a. When the nozzle 8d is installed vertically, there is a concern that the nozzle 8d may shake or fall down due to a force generated by the gas being ejected. In order to suppress shaking or falling, a front end (tip) of the nozzle 8d is capable of being pressed against an inner wall surface of the inner tube 4B by adjusting the bolt 34a. When the nozzle 8d is pressed, an inner structure of the nozzle 8d does not contact the inner wall surface of the inner tube 4B.

An installation operation of the nozzle 8e is similar to that of the nozzle 8d. Configurations including a gas inlet port for introducing the gas into the nozzle 8e, a gas supply pipe, a nozzle base, a support structure for fixing the nozzle base and a bracket and configurations including the gas inlet port 38, the gas supply pipe 31, the nozzle base 32, the support structure 33 and the bracket 35 are arranged symmetrically with respect to the line C-C shown in FIG. 2.

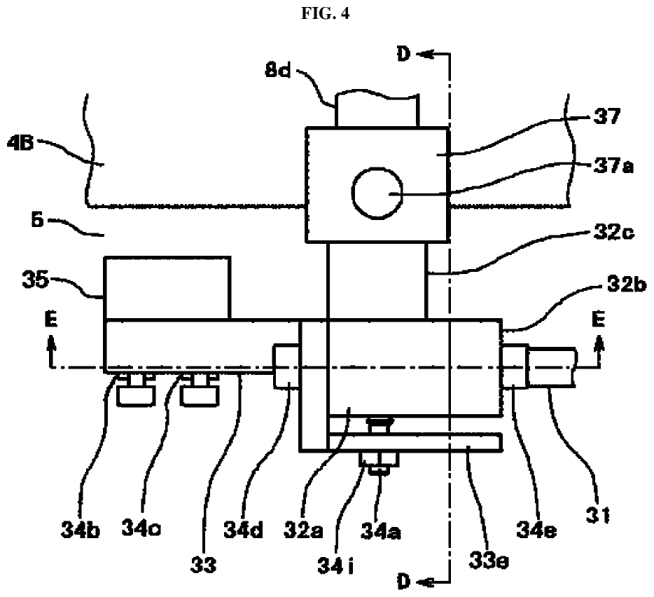

The nozzle base 32 and its periphery will be described with reference to FIGS. 4 through 8. As shown in FIG. 4, the nozzle base 32 is constituted by a first engaging portion 32a, a second engaging portion 32b and an installation portion 32c. Each of the first engaging portion 32a and the second engaging portion 32b is of a polygonal block shape. The installation portion 32c is of a cylindrical shape extending (rising) from an upper surface of the first engaging portion 32a and fitted with the nozzle 8d. For example, the first engaging portion 32a and the installation portion 32c may be formed as a single body. The first engaging portion 32a and the second engaging portion 32b are joined on a plane (also referred to as a “second joint surface 32j”) substantially parallel to a plane passing through the center of the process vessel and a central axis of the nozzle 8d. In the present specification, the second joint surface 32j may refer to a surface parallel to a direction in which the nozzle 8d extends and parallel to a line connecting the nozzle 8d and the center of the process vessel or a surface including a central axis of the process vessel, and may also refer to a surface tilted in a direction to be tilted by the bolt 34a. The gas supply pipe 31 is connected to a side surface of the second engaging portion 32b opposite to the first engaging portion 32a.

The installation portion 32c is embodied by a double tube structure including an outer pipe (not shown) and an inner pipe (not shown), and the nozzle 8d is inserted into an annular space between the outer pipe and the inner pipe. A cover 37 configured to cover a periphery of the outer pipe is provided on an upper portion of the installation portion 32c. It is possible to prevent a positioning structure (not shown: which is configured to determine an orientation of the nozzle 8d with respect to the installation portion 32c) from falling off by the cover 37. The inner pipe communicates with a flow path 32d of a first engaging portion 32a described later.

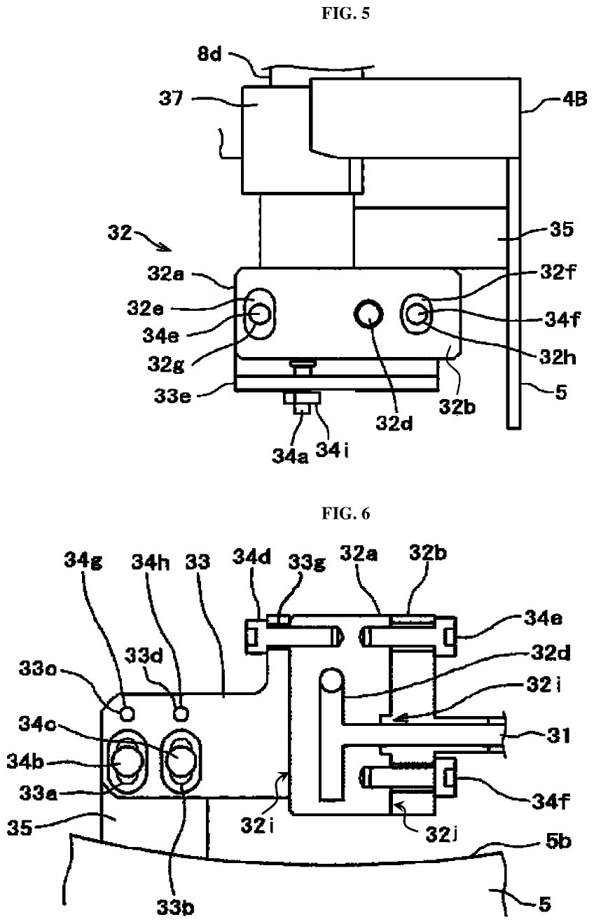

As shown in FIG. 5, the second engaging portion 32b is provided with the flow path 32d penetrating in an extending direction of the gas supply pipe 31 and airtightly connected to the gas supply pipe 31 by a welding and the like and two elongated holes 32e and 32f penetrating in the same direction. Further, the first engaging portion 32a is provided with two tapped holes 32g and 32h at positions corresponding to the elongated holes 32e and 32f. Each of the elongated holes 32e and 32f is elongated in an arc direction of a circle centered on the flow path 32d of a circular shape in the nozzle base 32, and the flow path 32d is disposed between the elongated holes 32e and 32f. A bolt 34e passes through the elongated hole 32e and is screwed into the tapped hole 32g, and a bolt 34f passes through the elongated hole 32f and is screwed into the tapped hole 32h. Thereby, each of the first engaging portion 32a and the second engaging portion 32b can be rotated around the flow path 32d to change an angle thereof within a predetermined range. As a result, without applying a torsional load to the gas supply pipe 31, it is possible to fasten and fix a posture with an appropriate amount of a nozzle tilt.

Further, as shown in FIG. 6, on the second joint surface 32j of the nozzle base 32, a spigot shape (spigot joint) is formed in order to align a center of the flow path 32d. The spigot joint comprises a concave portion on the first engaging portion 32a side and a convex portion on the second engaging portion 32b side. The flow path 32d communicates with the gas supply pipe 31. The spigot shape may also act to increase an airtightness of a joint.

As shown in FIGS. 4 and 6, the bracket 35 serving as a mounting structure extending horizontally is provided on the inner wall surface 5b of the manifold 5 by the welding and the like. One end of the support structure 33 is fixed to a lower surface of the bracket 35 by bolts 34b and 34c, and supports the nozzle base 32 with a cantilever beam structure. The support structure 33 is rigidly joined (that is, joined in a manner of a rigid joint) to a side surface of the first engaging portion 32a (also referred to as a “first joint surface”), which is located opposite to the second engaging portion 32b without facing the inner wall surface 5b, by a bolt (joint bolt) 34d serving as a fastening structure (fastener). Thereby, the support structure 33 fixes the first engaging portion 32a. The bolt 34d passes through a vertically elongated hole (slotted hole) 33g provided in the support structure 33, and is screwed into the first engaging portion 32a. In the present specification, the term “rigid joint” is used to distinguish it from a rotatable joint such as a pin joint and a ball joint. The first joint surface 32i is substantially parallel to the second joint surface 32j between the first engaging portion 32a and the second engaging portion 32b.

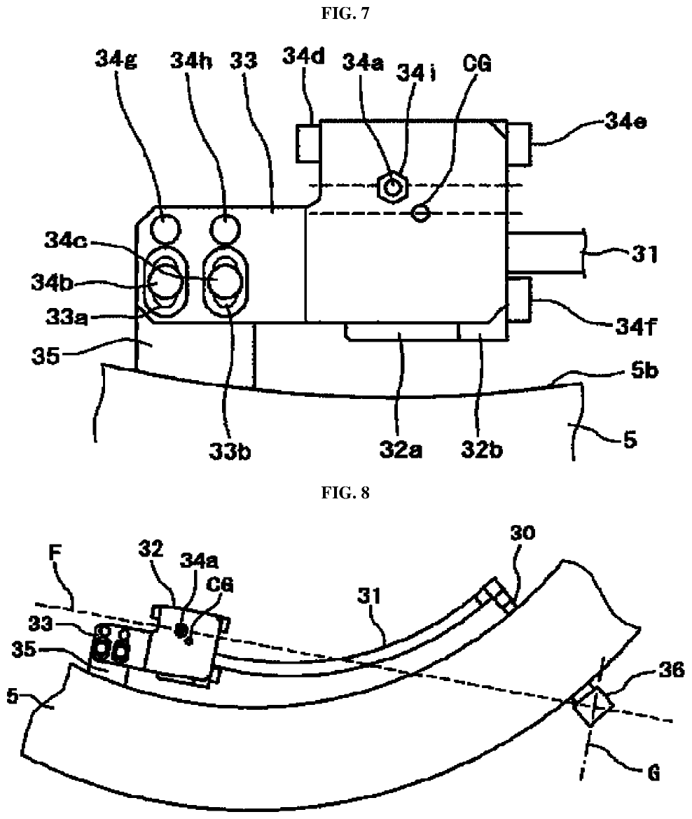

The support structure 33 includes an angle structure 33e extending downward from a position at which the support structure 33 is rigidly joined to the nozzle base 32 (that is, a position fixed by the bolt 34d) and then extending laterally below the nozzle base 32. The bolt 34a is provided so as to pass through the angle structure 33e in the vertical direction and to be screwed with the angle structure 33e so as to support a lower surface of the first engaging portion 32a of the nozzle base 32. As shown in FIGS. 7 and 8, the bolt 34a is positioned closer to the center of the process vessel than a center of gravity CG of an integrated body (which is a nozzle assembly) including the nozzle 8d, the nozzle base 32 and the gas supply pipe 31. When the bolt 34a is pushed up in a state where the bolt 34d is not sufficiently tightened, a weight (load) of the nozzle assembly is applied to the bolt 34a and the O-ring of the connecting structure 36 at two points. By pushing up the bolt 34a from a center portion of the reaction tube 4 rather than the center of gravity CG, it is possible to tilt the nozzle 8d toward an outside of the reaction tube 4, and it is also possible to press the front end of the nozzle 8d against an inner wall of the inner tube 4B.

For example, when the center of gravity CG is positioned on a straight line F connecting the bolt 34a and the O-ring of the connecting structure 36 shown in FIG. 8, the nozzle 8d tilts in the horizontal direction by rotating around a rotation axis G with the O-ring of the connecting structure 36 as a fulcrum, but does not tilt toward the center of the process vessel. However, it cannot be tilted toward the inner wall of the inner tube 4B by adjusting the bolt 34a. As a result, in a case where the nozzle 8d is installed vertically and the nozzle 8d may shake or fall down in a front-rear direction due to the force generated by the gas being ejected, the nozzle 8d may shake and may contact with the boat 21 during a film-forming process described later. Thereby, there is a concern that the nozzle 8d or the boat 21 is damaged.

According to the present embodiments, in order to maintain a tilted posture of the nozzle base 32, the bolt 34d is threaded such that the bolt 34d is further tightened as the bolt 34a pushes the nozzle base 32 more upward. In other words, the bolt 34d is further tightened as the nozzle 8 tilts more in a direction in which a front end (tip) of the nozzle 8 faces toward the outside of the reaction tube 4. Conversely, the more the bolt 34d is tightened, the more the nozzle 8 is pressed in the direction in which the front end of the nozzle 8 faces the outside of the reaction tube 4. Further, a plurality of bolts including the bolt 34d may be provided. In such a case, the plurality of bolts including the bolt 34d are tightened by being rotated in the substantially same direction.

As shown in FIG. 6, the bolts 34e and 34f face the bolt 34d, wherein the bolts 34e and 34f are fixed at the side surface of the first engaging portion 32a (that is, the second joint surface 32j) so as to fasten the first engaging portion 32a with the second engaging portion 32b, and the bolt 34d are fixed at another side surface of the first engaging portion 32a (that is, the first joint surface 32i) so as to fasten the support structure 33 with the nozzle base 32. Each of the bolts 34d, 34e and 34f is threaded in such a direction that the front end of the nozzle 8d is tilted toward the inner wall of the inner tube 4B by tightening each of the bolts 34d, 34e and 34f. That is, when the bolts 34e and 34f are right-hand threaded, the bolt 34d is left-hand threaded. Further, another nozzle base for the nozzle 8e is bilaterally symmetrical to the nozzle base 32 for the nozzle 8d, a bolt that fastens a joint surface of the nozzle base of the nozzle 8e is left-hand threaded, and a bolt that fastens the nozzle base of the nozzle 8e and a support structure thereof is right-hand threaded.

As shown in FIG. 6, the support structure 33 is provided with two through-holes 33a and 33b for screwing the bolts 34b and 34c serving as first bolts into the bracket 35, and is also provided with two tapped holes 33c and 33d penetrating therethrough. By screwing bolts 34g and 34h serving as second bolts into the tapped holes 33c and 33d, respectively, and pressing (contacting) the lower surface of the bracket 35, it is possible to adjust a parallelism (tilt or inclination) of the support structure 33 in a left-right direction (circumferential direction). A counterbore is provided around the through-holes 33a and 33b, and at least a portion of head structure of each of the bolts 34b and 34c is accommodated therein.

A procedure of attaching the nozzle base 32 will be described. First, the support structure 33 is fully tightened to the bracket 35 with the bolts 34b and 34c. However, the bolt 34a is temporarily tightened at a low level. Subsequently, the front end of the nozzle 8d is brought into contact with the inner wall of the inner tube 4B such that the nozzle base 32 is placed on the bolt 34a, the tilt is adjusted and the bolts 34e and 34f are fully tightened, and the bolt 34d is temporarily tightened. In such a state, due to a positional relationship of the center of gravity CG described above, the nozzle 8d is in a state in which it tends to fall down and be brought into contact with the inner wall of the inner tube 4B, and the bolt 34a pushes up the nozzle 8d barely to maintain the nozzle 8d in contact with the inner wall of the inner tube 4B. Subsequently, a pressurization is applied by the bolt 34a such that the bolt 34a is fully tightened to a nut 34i. In the present specification, the “pressurization” applied by the bolt 34a may refer to a strength with which the front end of the nozzle 8d is pressed against the inner wall surface of the inner tube 4B. Since the nozzle 8d is located at the bottom of the bulges 43 of a U-shape provided on the inner wall of the inner tube 4B, the nozzle 8d does not tilt in the left-right direction even when the pressurization is applied by the bolt 34a. An amount of the pressurization can be quantitatively and reproducibly defined (that is, can be set) by an additional rotation angle (rotation amount) of the bolt 34a. Thereafter, the nozzle base 32 and the support structure 33 are fully tightened with the bolt 34d. Since the bolt 34d was temporarily tightened, a pressurization is further applied by the bolt 34a. When the nozzle 8d is tilted in the left-right direction due to a poor flatness/parallelism of the configuration, the bolts 34g and 34h are pushed and pulled for adjustment. When there is no tilt, the bolts 34g and 34h may not be used. As long as a relative positional accuracy between the bracket 35 and the reaction tube 4 can be maintained high, a part of the support structure 33 and the bracket 35 may be formed as a single body. In such a case, when the angle structure 33e is configured to be detachable by a bolt or the like, it is not possible to prevent the nozzle 8d from being pulled downward and being detached.

Subsequently, an exemplary sequence of a process (hereinafter, also referred to as the “film-forming process”) of forming a film on the substrate, which is a part of the manufacturing process of the semiconductor device performed by using the substrate processing apparatus 1 described above, will be described. The present embodiments will be described by way of an example in which the film is formed on the wafer 7 by providing two or more nozzles 8 and by alternately supplying a first process gas (that is, the source gas) to the wafer 7 serving as the substrate through the nozzle 8a and a second process gas (that is, the reactive gas) to the wafer 7 serving as the substrate through the nozzle 8b. In addition, when the gas supplier shown in FIG. 1 serves as a gas supplier for the nozzle 8a, the gas supply pipe 9, the MFC 10, the valve 11, the gas supply pipe 12, the MFC 13 and the valve 14 of the gas supplier shown in FIG. 1 may also be referred to as a gas supply pipe 9a, an MFC 10a, a valve 11a, a gas supply pipe 12a, an MFC 13a and a valve 14a, respectively. Further, when the gas supplier shown in FIG. 1 serves as a gas supplier for the nozzle 8b, the gas supply pipe 9, the MFC 10, the valve 11, the gas supply pipe 12, the MFC 13 and the valve 14 of the gas supplier shown in FIG. 1 may also be referred to as a gas supply pipe 9b, an MFC 10b, a valve 11b, a gas supply pipe 12b, an MFC 13b and a valve 14b, respectively.

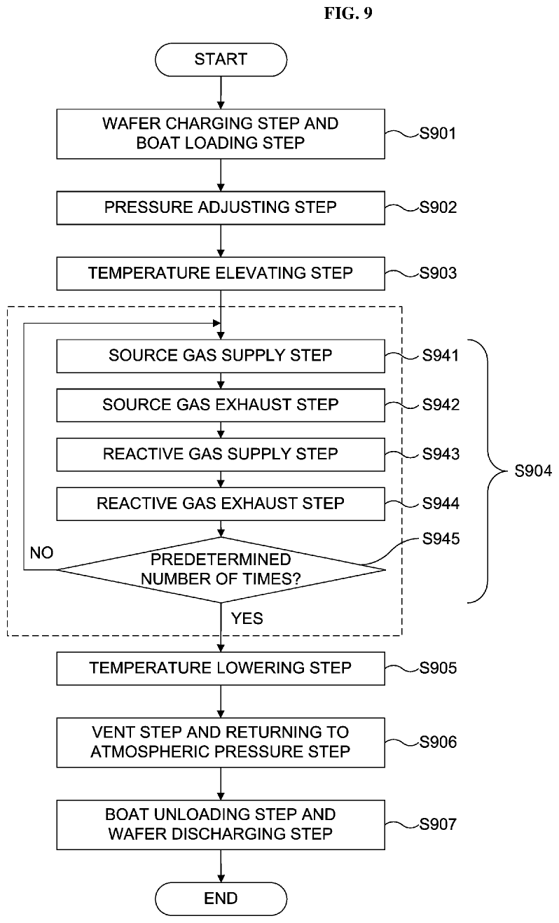

Hereinafter, with reference to FIG. 9, an example of forming a predetermined film on the wafer 7 by using a silicon-containing gas such as a silane-based gas as the source gas and a nitrogen-containing gas as the reactive gas will be described. In the following description, operations of components constituting the substrate processing apparatus 1 are controlled by the controller 29.

In the film-forming process according to the present embodiments, the film is formed on the wafer 7 by performing a cycle a predetermined number of times (once or more). The cycle may include: a step of supplying the source gas to the wafer 7 in the process chamber 6 (S941); a step of removing the source gas (residual gas) from the process chamber 6 (S942); a step of supplying the reactive gas to the wafer 7 in the process chamber 6 (S943); and a step of removing the reactive gas (residual gas) from the process chamber 6 (S944). The steps of the cycle are performed non-simultaneously.

In the present specification, the term “wafer” may refer to “a wafer itself (that is, a bare wafer)”, or may refer to “a wafer and a stacked structure (aggregated structure) of a predetermined layer (or layers) or a film (or films) formed on a surface of the wafer”. Similarly, the term “a surface of a wafer” may refer to “a surface of a wafer itself”, or may refer to “a surface of a predetermined layer or a film formed on a wafer, i.e. a top surface (uppermost surface) of the wafer as a stacked structure”. In the present specification, the terms “substrate” and “wafer” may be used as substantially the same meaning.

<S901: Wafer Charging Step and Boat Loading Step>

First, after a standby state of an apparatus (that is, the substrate processing apparatus 1) is released, the wafers 7 are transferred (charged) into the boat 21 (wafer charging step), and the boat 21 with the wafers 7 charged therein is transferred (loaded) into the process chamber 6 by the boat elevator 27 (boat loading step). When loading the boat 21 into the process chamber 6, the controller 29 sets a predetermined small flow rate (for example, 50 sccm or less) for the MFC 25, and controls the valve 26 to open. Thereby, a small amount of the N₂ gas (which serves as shaft purge gas) may flow out from the rotator 23. When the boat 21 is completely loaded into the process chamber 6, the seal cap 19 airtightly (hermetically) seals the lower end of the manifold 5 via the O-ring 19A. In addition, a supply of a purge gas such as the shaft purge gas may be started by allowing the valve 26 or the valve 14 to be open even during the standby state (i.e., constantly open) before the wafer charging step. By supplying the shaft purge gas through the valve 26, it is possible to prevent (or suppress) particles from outside from adhering to the heat insulating assembly 22 during the wafer charging step, and by supplying the purge gas through the valve 14, it is possible to suppress a backflow of a gas such as air into a nozzle such as the nozzle 8.

<S902: Pressure Adjusting Step>

The vacuum pump 18 vacuum-exhausts (decompression-exhausts) the inner atmosphere of the process chamber 6 (that is, a space in which the wafers 7 are accommodated) until the inner pressure of the process chamber 6 reaches and is maintained at a predetermined pressure (vacuum degree). In the present step, the inner pressure of the process chamber 6 is measured by the pressure sensor 16, and the APC valve 17 is feedback-controlled based on the pressure information measured by the pressure sensor 16. The vacuum pump 18 is continuously operated until at least a processing of the wafer 7 is completed.

<S903: Temperature Elevating Step>

Further, the heater 3 heats the process chamber 6 such that a temperature of the wafer 7 in the process chamber 6 reaches and is maintained at a predetermined temperature. In the present step, the state of electric conduction to the heater 3 is feedback-controlled based on the temperature information detected by the temperature sensor 28 such that a predetermined temperature distribution of the inner temperature of the process chamber 6 is obtained. The heater 3 continuously heats the process chamber 6 until at least the processing of the wafer 7 is completed.

<S904: Film-forming Step>

When the inner temperature of the process chamber 6 is stabilized at a process temperature (which is set in advance), the following four steps (sub-steps), that is, a step S941, a step S942, a step S943 and a step S944 are sequentially performed. During the film-forming step S904, the rotator 23 rotates the boat 21 via a rotating shaft 66 such that the wafers 7 are rotated.

<S941: Source Gas Supply Step>

In the present step, by supplying the source gas to the wafer 7 in the process chamber 6, a silicon-containing layer serving as a first layer is formed on an uppermost surface of the wafer 7. Specifically, the valve 11a is opened to supply the source gas into the gas supply pipe 9a. A flow rate of the source gas supplied into the gas supply pipe 9a is adjusted by the MFC 10a. The source gas whose flow rate is adjusted is then supplied into the process region A of the process chamber 6 through the nozzle holes 8H of the nozzle 8a, the nozzle chamber 42 and the supply slits 4F, and is exhausted through the exhaust pipe 15 via the main exhaust port 4E, the exhaust space S and the exhaust outlet 4D. In the present step, simultaneously with a supply of the source gas, the valve 14a is opened to supply the N₂ gas into the gas supply pipe 12a. A flow rate of the N₂ gas supplied into the gas supply pipe 12a is adjusted by the MFC 13a. The N₂ gas whose flow rate is adjusted is then supplied into the process region A of the process chamber 6 together with the source gas through the nozzle holes 8H of the nozzle 8a, the nozzle chamber 42 and the supply slits 4F, and is exhausted through the exhaust pipe 15 via the main exhaust port 4E and the exhaust space S. In the present step, simultaneously with the supply of the source gas, the N₂ gas is also supplied into the process region A of the process chamber 6 through the nozzle holes 8H of the nozzles 8d and 8e, and is exhausted through the exhaust pipe 15 via the main exhaust port 4E, the exhaust space S and the exhaust outlet 4D. In the present step, the controller 29 performs a constant pressure control with a first pressure as a target pressure.

<S942: Source Gas Exhaust Step>

After the first layer is formed, the valve 11a is closed to stop the supply of the source gas into the process chamber 6, and a control is performed with the APC valve 17 fully opened. As a result, the inner atmosphere of the process chamber 6 is vacuum-exhausted to remove a residual gas such as the source gas in the process chamber 6 which did not react or which did contribute to a formation of the first layer from the process chamber 6. In the present step, an exhaust gas whose temperature is close to the inner temperature of the process chamber 6 passes through the exhaust outlet 4D, and the heat is transferred from the exhaust gas to the exhaust outlet 4D and its peripheries. Further, the residual gas may be purged by the N₂ gas supplied into the process chamber 6 with the valve 14a maintained open. The flow rate of the purge gas through the nozzle 8a is set such that a partial pressure of a low vapor pressure gas is lower than a saturated vapor pressure in an exhaust path, or such that a flow velocity of the gas in the reaction tube 4 is greater than a diffusion speed of the gas. Usually, the flow rate of the purge gas through the nozzle 8a is much greater than that of a vent gas and that of the shaft purge gas which are small.

<S943: Reactive Gas Supply Step>

After the step S942 is completed, the reactive gas is supplied to the wafer 7 in the process chamber 6, that is, to the first layer formed on the wafer 7. The reactive gas is thermally activated. The thermally activated reactive gas reacts with at least a portion of the first layer (that is, the silicon-containing layer) formed on the wafer 7 in the step S941. As a result, the first layer is modified (changed) into a second layer containing silicon (Si) and nitrogen (N), that is, a silicon nitride layer. In the step S943, the valves 11b and 14b are controlled in the same manners as the valves 11a and 14a in the step S941. Specifically, a flow rate of the reactive gas is adjusted by the MFC 10b. The reactive gas whose flow rate is adjusted is then supplied into the process region A of the process chamber 6 through the nozzle holes 8H of the nozzle 8b, the nozzle chamber 42 and the supply slits 4F, and is exhausted through the exhaust pipe 15 via the main exhaust port 4E and the exhaust space S. In the present step, simultaneously with a supply of the reactive gas, the N₂ gas is also supplied into the process region A of the process chamber 6 through the nozzle holes 8H of the nozzles 8d and 8e, and is exhausted through the exhaust pipe 15 via the main exhaust port 4E, the exhaust space S and the exhaust outlet 4D. In the present step, the controller 29 performs the constant pressure control with a second pressure as the target pressure. For example, each of the first pressure and the second pressure may be set to a pressure within a range from 100 Pa to 5,000 Pa, preferably from 100 Pa to 500 Pa.

<S944: Reactive Gas Exhaust Step>

After the second layer is formed, the valve 11b is closed to stop the supply of the reactive gas into the process chamber 6, and the constant pressure control with a zero (0) pressure as the target pressure is performed (that is, a full-open pressure control is performed). As a result, the inner atmosphere of the process chamber 6 is vacuum-exhausted to remove a residual gas such as the reactive gas in the process chamber 6 which did not react or which did contribute to a formation of the second layer from the process chamber 6. In the step S944, similar to the step S942, a small amount of the N₂ gas may be supplied into the process chamber 6 as the purge gas. The ultimate pressure in the source gas exhaust step S942 or the reactive gas exhaust step S944 may be 100 Pa or less, preferably may be set to a pressure within a range from 10 Pa to 50 Pa. The inner pressure of the process chamber 6 when the gas is supplied may be different from that of the process chamber 6 when the gas is exhausted by 10 times or more.

<S945: Performing Predetermined Number of Times>

By performing the cycle wherein the steps S941 through S944 described above are performed sequentially and non-simultaneously in this order a predetermined number of times (n times), the film with a predetermined composition and a predetermined thickness can be formed on the wafer 7. Thicknesses of the first layer and the second layer formed in the steps S941 and S943, respectively, may not be self-limiting. Therefore, in such a case, in order to obtain a stable quality of the film, it is preferable that a concentration of the gas exposed to the wafer 7 and a supply time (time duration) of the gas exposed to the wafer 7 are precisely controlled with a high reproducibility. In addition, the steps S941 and S942 or the steps S943 and S944 may be further repeatedly performed a plurality of times within the cycle.

<S905: Temperature Lowering Step>

In the present step, the inner temperature of the process chamber 6 is gradually lowered, when necessary, by stopping the step S903 which has been continued during the film-forming step or by re-setting the predetermined temperature of the step S903 to a lower temperature.

<S906: Vent Step and Returning to Atmospheric Pressure Step>

After the film-forming step S904 is completed, the valve 14 and a valve (not shown) are opened. Then, the N₂ gas is supplied into the process chamber 6 through the gas supply pipe 12 and a gas supply pipe (not shown), and is exhausted through the exhaust pipe 15. As a result, the inner atmosphere of the process chamber 6 is replaced with the inert gas (substitution by inert gas), and the source gas remaining in the process chamber 6 and by-products are removed (purged) from the process chamber 6. Thereafter, the APC valve 17 is closed, and N₂ gas is filled until the inner pressure of the process chamber 6 is returned to a normal pressure (atmospheric pressure) (returning to atmospheric pressure step). The steps S905 and S906 may be performed in parallel, or the step S906 may be performed before the step S905.

<S907: Boat Unloading Step and Wafer Discharging Step>

The seal cap 19 is slowly lowered by the boat elevator 27 and the lower end of the manifold 5 is opened. Then, the boat 21 with the processed wafers 7 charged therein is unloaded (transferred) out of the reaction 4 through the lower end of the manifold 5 (boat unloading step). Then, the processed wafers 7 are discharged (transferred) from the boat 21 by a transfer device (not shown) (wafer discharging step).

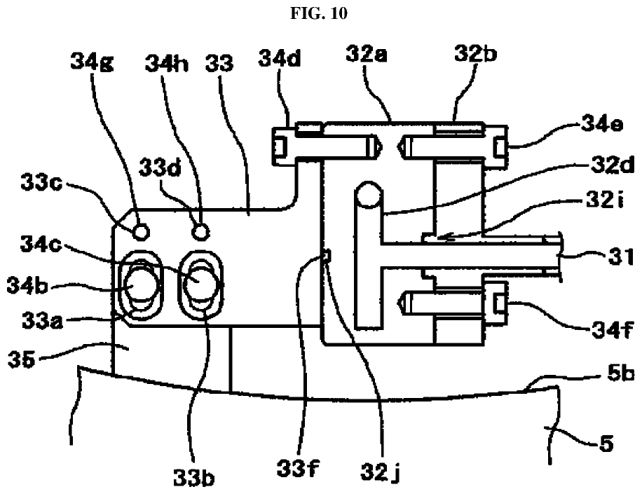

A modified example of the nozzle base 32 and configurations around the nozzle base 32 will be described with reference to FIG. 10. FIG. 10 is a diagram corresponding to FIG. 6. A pin 33f and a boss (which is a hole) 32j may be provided on the support structure 33 and the first engaging portion 32a of the nozzle base 32 on an extension line of the gas supply pipe 31, respectively. As a result, a rotation center of a tilt is positioned. An elongated hole 33g allows the nozzle base 32 to rotate within a predetermined range around the pin 33f and boss 32j. The pin 33f and the boss 32j are preferably provided at least on the manifold 5 rather than the bolt 34a. In addition, a clearance fit between the pin 33f and the boss 32j is sufficient, and a precision between the pin 33f and the boss 32j may not be required.

According to the present embodiments, it is possible to obtain one or more of the following effects.

(a) A tilt-adjusting structure (for example, the bolt 34a) configured to adjustably push or pull a lower surface of the nozzle base 32 is provided at a position shifted toward the center of the process vessel from the center of gravity of the nozzle assembly including the nozzle 8d and the nozzle base 32. As a result, it is possible to rigidly fix the nozzle 8d in a state in which a desired front-rear tilt is set. Since the fulcrum is arranged closer to the center of the process vessel than the center of gravity, it does not fall inward due to aging or the like.

(b) The gas supply pipe 31 extending laterally along the inner wall surface 5b of the manifold 5 and communicating with the flow path 32d on the side surface of the nozzle base 32 opposite to the support structure 33 is provided. Thereby, it is possible to improve a degree of freedom in an installation position of the nozzle 8d, and as a result, it is possible to improve a uniformity of the processing of the wafer 7 between the wafers 7.

(c) The nozzle base 32 and the support structure 33 are rigidly joined by one or more bolts (for example, the bolt 34d) at a plane substantially parallel to the direction in which the nozzle 8d extends and substantially parallel to the line connecting the nozzle 8d and the center of the process vessel (for example, the plane tilted in the direction to be tilted by the tilt-adjusting structure), and the bolt 34d is either a right-hand thread or a left-hand thread such that the bolt 34d is further tightened as the tilt-adjusting structure (bolt 34a) pushes the nozzle base 32 more upward. As a result, the pressurization is further applied to the nozzle 8d by the tilt-adjusting structure (bolt 34a) while the nozzle 8d is in contact with the inner wall of the inner tube 4B. Thereby, it is possible to prevent the nozzle 8d from rubbing or colliding against other structures.

(d) The center of gravity of the nozzle assembly including the gas supply pipe 31 is provided closer to the inner wall surface of the inner tube 4B than a straight line connecting a point where the gas inlet port 38 supports the gas supply pipe 31 and a point where the tilt-adjusting structure (bolt 34a) supports the nozzle base 32. As a result, since the nozzle 8d is fixed in such a manner that the nozzle 8d can be supported at only the two points, it is possible to prevent the gas inlet port 38 from being subjected to an excessive force and causing a leakage.

(e) The flange tube (that is, the manifold 5) is provided with the bracket 35 extending inward from a circumferential surface thereof, and the support structure 33 is detachably fastened at one end thereof to a bottom surface (lower surface) of the bracket 35 by the bolts 34b and 34c. Further, the support structure 33 supports the nozzle base 32 with the cantilever beam structure. As a result, it is possible to reduce a gap between the lower portion of the process vessel and the boat 21.

(f) The bolts 34b, 34c, 34g and 34h may be classified into: a first bolt (such as the bolts 34b and 34c) that is screwed into the bottom surface of the bracket 35 and passes through the support structure 33; and a second bolt (such as the bolts 34g and 34h) that is screwed into the support structure 33 and abuts on the bottom surface of the bracket 35. Thereby, it is also possible to adjust the tilt in the circumferential direction (horizontal direction).

(g) The support structure 33 includes the angle structure 33e extending downward from the position at which the support structure 33 is rigidly joined to the nozzle base 32 and then extending laterally below the nozzle base 32, and the tilt-adjusting structure (bolt 34a) is provided on the angle structure 33e. As a result, a common configuration can serve as the fulcrum of the nozzle base 32 and a configuration rigidly connected (fixed). Thereby, it is possible to enhance a workability.

(h) The nozzle base 32 is embodied by a split structure in which the first engaging portion 32a and the second engaging portion 32b are separated, and the joint surfaces of the first engaging portion 32a and the second engaging portion 32b is set so as to be tilted in a direction of rotation for tilting the nozzle. As a result, it is possible to facilitate the installation operation of the nozzle, and it is also possible to adjust the tilt of the nozzle without causing the leakage in the connecting structure 36.

### OTHER EMBODIMENTS OF PRESENT DISCLOSURE

While the technique of the present disclosure is described in detail by way of the embodiments described above, the technique of the present disclosure is not limited thereto. The technique of the present disclosure may be modified in various ways without departing from the scope thereof. Those skilled in the art may widely apply the embodiments described above to a heat treatment process of the substrate under a depressurized state. For example, the technique of the present disclosure is not limited to a hot wall type reaction tube, and may be applied to a cold wall type reaction tube by using a lamp heating or induction heating. For example, the technique of the present disclosure may be applied to various types of reaction tubes including the reaction tube of the double tube structure as shown in FIG. 1, the reaction tube with a buffer (duct) as shown in FIG. 2, and a reaction tube of a single tube, as shown in FIG. 5.

According to some embodiments of the present disclosure, it is possible to maintain the nozzle at an appropriate tilt.

What is claimed is:

1. A substrate processing apparatus comprising:
a nozzle arranged along an inner wall surface of a process vessel and provided at least in a lower portion of the process vessel with a gap between the nozzle and the inner wall surface of the process vessel;
a nozzle base configured to support the nozzle, wherein a flow path communicating with the nozzle is provided in the nozzle base;
a support structure provided along the inner wall surface and joined to a first joint surface of the nozzle base, wherein the first joint surface of the nozzle base does not face the inner wall surface; and
a tilt-adjusting structure configured to be capable of adjusting a tilt of the nozzle base at a position shifted toward a center of the process vessel and away from a center of gravity of a nozzle assembly comprising the nozzle and the nozzle base.

2. The substrate processing apparatus of claim 1, further comprising
a gas supply pipe provided along the inner wall surface and communicating with the flow path on a side surface of the nozzle base opposite to the support structure.

3. The substrate processing apparatus of claim 2, wherein the process vessel is of a cylindrical shape extending laterally, and the nozzle extends vertically along the inner wall surface, and
wherein the nozzle base and the support structure extend laterally along the inner wall surface and are joined by one or more fastening structures at a plane substantially parallel to a direction in which the nozzle extends and substantially parallel to a line connecting the nozzle and the center of the process vessel.

4. The substrate processing apparatus of claim 3, wherein each of the one or more fastening structures comprises a bolt comprising either a right-hand thread or a left-hand thread such that each of the one or more fastening structures is further tightened as the tilt-adjusting structure pushes the nozzle base more upward.

5. The substrate processing apparatus of claim 3, wherein each of the one or more fastening structures comprises a bolt comprising either a right-hand thread or a left-hand thread such that the one or more fastening structures is further tightened as the nozzle tilts more in a direction in which a front end of the nozzle faces toward an outside of the process vessel.

6. The substrate processing apparatus of claim 3, wherein the process vessel comprises: a reaction tube provided with an opening at a lower end thereof; and a flange tube made of a metal and connected to the opening of the reaction tube,
wherein a gas inlet port, through which an end of the gas supply pipe opposite to the nozzle base is inserted, is provided on a side surface of the flange tube, and
wherein the nozzle assembly further comprises the gas supply pipe, and the center of gravity of the nozzle assembly is provided closer to an inner wall surface of the reaction tube than a straight line connecting a point where the gas inlet port supports the gas supply pipe and a point where the tilt-adjusting structure supports the nozzle base.

7. The substrate processing apparatus of claim 6, wherein the flange tube is provided with a bracket extending inward from a circumferential surface of the flange tube, and the support structure is fastened at one end of the support structure to a bottom surface of the bracket by a joint bolt to support the nozzle base.

8. The substrate processing apparatus of claim 7, wherein each of the one or more fastening structures comprises:
a first bolt that is screwed into the bracket and passes through the support structure; and
a second bolt that is screwed into the support structure and abuts on the bottom surface of the bracket.

9. The substrate processing apparatus of claim 1, wherein the support structure is provided with an angle structure extending downward from a position at which the support structure is joined to the nozzle base and then extending laterally below the nozzle base, and the tilt-adjusting structure is provided on the angle structure.

10. The substrate processing apparatus of claim 1, wherein the nozzle base comprises a first engaging portion and a second engaging portion that are formed separably and joined by a second joint surface.

11. The substrate processing apparatus of claim 10, wherein each of the first engaging portion and the second engaging structure is provided with a spigot structure around the flow path penetrating the second joint surface.

12. The substrate processing apparatus of claim 10, wherein each of the first engaging portion and the second engaging portion is capable of being rotated around the flow path penetrating the second joint surface to change an angle thereof.

13. The substrate processing apparatus of claim 10, wherein the first joint surface is substantially parallel to the second joint surface.

14. The substrate processing apparatus of claim 1, wherein the nozzle is fixed by the support structure with a front end of the nozzle pressed against the inner wall surface of the process vessel.

15. The substrate processing apparatus of claim 14, wherein each of the tilt-adjusting structure comprises a bolt penetrating the support structure in a vertical direction and screwed into the support structure, and each of the one or more tilt-adjusting structures is configured such that a strength of pressing the front end of the nozzle against the inner wall surface is capable of being set quantitatively in accordance with a rotation amount of the bolt.

16. A nozzle assembly comprising:
a nozzle base configured to be capable of supporting a nozzle such that the nozzle is arranged along an inner wall surface of a process vessel and provided at least in a lower portion of the process vessel with a gap between the nozzle and the inner wall surface of the process vessel, wherein a flow path communicating with the nozzle is provided in the nozzle base;
a support structure provided along the inner wall surface and joined to a first joint surface of the nozzle base, wherein the first joint surface of the nozzle base does not face the inner wall surface; and
a tilt-adjusting structure configured to be capable of adjusting a tilt of the nozzle base at a position shifted toward a center of the process vessel and away from a center of gravity of the nozzle assembly.

17. A substrate processing method comprising:
(a) loading a wafer into a process vessel of a substrate processing apparatus, wherein the substrate processing apparatus comprises:
a nozzle arranged along an inner wall surface of the process vessel and provided at least in a lower portion of the process vessel with a gap between the nozzle and the inner wall surface of the process vessel;
a nozzle base configured to support the nozzle, wherein a flow path communicating with the nozzle is provided in the nozzle base;
a support structure provided along the inner wall surface and joined to a first joint surface of the nozzle base, wherein the first joint surface of the nozzle base does not face the inner wall surface; and
a tilt-adjusting structure configured to be capable of adjusting a tilt of the nozzle base at a position shifted toward a center of the process vessel and away from a center of gravity of a nozzle assembly comprising the nozzle and the nozzle base; and
(b) processing the wafer.

18. A method of manufacturing a semiconductor device comprising the substrate processing method of claim 17.

19. A non-transitory computer-readable recording medium storing a program that causes, by a computer, a substrate processing apparatus to perform a process comprising the substrate processing method of claim 17.
